(19) United States
(12) Patent Application Publication
(10) Pub. No.: US 2025/0314695 A1
(43) Pub. Date: Oct. 9, 2025

(54) TEST PROBE ASSEMBLY FOR HIGH FREQUENCY DEVICE CHARACTERIZATION

(71) Applicant: XCERRA CORPORATION, Norwood, MA (US)

(72) Inventors: Martin CAVEGN, St. Paul, MN (US); Robert MORIN, St. Paul, MN (US); Jason MROCZKOWSKI, St. Paul, MN (US); Scott HANSON, St. Paul, MN (US); Aaren LONKS, St. Paul, MN (US)

(21) Appl. No.: 18/630,732

(22) Filed: Apr. 9, 2024

(51) Int. Cl. G01R 31/311

(52) U.S. Cl. CPC G01R 31/311

(57) ABSTRACT

A test probe assembly includes a mounting fixture, a co-planar waveguide lead frame having a device contact point, where the co-planar waveguide lead frame is mounted to the mounting fixture, and at least one radio frequency (RF) connector assembly electrically coupled with the co-planar waveguide lead frame.

### TECHNICAL FIELD

Aspects relate to a test probe capable of probing non-coplanar contacts and related methods.

### TECHNICAL BACKGROUND

Radio Frequency (RF) characterization probes provide a precision impedance-matched contact geometry to probe small transmission line structures on semiconductor devices, printed circuit boards (PCBs), semiconductor wafers, or any other small geometries that need RF characterization.

RF characterization probes are available. However, the probes available on the current market are expensive, fragile, and not all are field-repairable. The current probes are made using a small coaxial cable and either machining the contact end of the probe or soldering small flanges onto the contact end to provide a coplanar termination. These are not field repairable nor are they configurable. Further, many current designs have low manufacturing yields.

### SUMMARY

Consistent with the present disclosure, a lead frame comprises a substrate having a first substrate side, a first ground sheet secured on the first substrate side, a second ground sheet secured on the first substrate side, the second ground sheet physically separated from the first ground sheet, and a signal conductor trace secured on the first substrate side between the first ground sheet and the second ground sheet, and the signal conductor trace terminating in a device contact.

In some embodiments, the lead frame further comprises a ground sheet gap separating the first ground sheet from the second ground sheet, the ground sheet gap contiguous with a conductor slot formed between the first ground sheet and the second ground sheet and the conductor slot contiguous with the signal conductor trace. In some embodiments, the ground sheet gap has a ground sheet gap center line, the signal conductor trace has a signal conductor trace center line, and the signal conductor trace center line and the ground sheet gap center line form an angle having an angle size greater than zero degrees and less than one-hundred eighty degrees. In some embodiments, the lead frame further comprises an adhesive to secure the first ground sheet to the substrate and to secure the second ground sheet to the substrate. In some embodiments, the adhesive has an adhesive thickness of between about zero and one-hundred microns. In some embodiments, the substrate has a substrate thickness of between about zero and two-hundred microns.

In some embodiments, wherein the first ground sheet has a first ground sheet thickness of between about thirteen and two-hundred and fifty microns. In some embodiments, the first ground sheet has a first ground sheet mounting and alignment first hole and a first ground sheet mounting and alignment second hole and the second ground sheet has a second ground sheet mounting and alignment first hole and a second ground sheet mounting and alignment second hole.

In some embodiments, the signal conductor trace has a signal conductor trace width, a first signal conductor trace gap located between the signal conductor trace and the first ground sheet has a first signal conductor trace gap width and a second signal conductor trace gap located between the signal conductor trace and the second ground sheet has a second signal conductor trace gap width, and the conductor slot has a width substantially equal to the signal conductor trace width plus the first signal conductor trace gap width and the second signal conductor trace gap width.

In some embodiments, the first ground sheet and the second ground sheet form a conductor slot that exposes a section of the first substrate side, the conductor slot is located between the ground sheet gap and the signal conductor trace. In some embodiments, the signal conductor trace has a signal conductor trace width, a first signal trace gap has a first signal trace gap width and a second signal trace gap has a second signal trace gap width, and the conductor slot has a conductor slot width substantially equal to the signal conductor trace width plus the first signal trace gap width and the second signal trace gap width.

In some embodiments, the signal conductor trace width is between about fifty and about six-hundred microns. In some embodiments, the lead frame includes an outside edge and the ground sheet gap extends from the conductor slot to the outside edge. In some embodiments, the conductor slot exposes a section of the first substrate side.

Consistent with the present disclosure, a test probe assembly comprises a mounting fixture, a lead frame mounted to the mounting fixture, and at least one radio frequency connector assembly electrically coupled with the lead frame. In some embodiments, the lead frame comprises a substrate having a first substrate side, a first ground sheet secured on the first substrate side, a second ground sheet secured on the first substrate side, the second ground sheet physically separated from the first ground sheet, and a signal conductor trace secured on the first substrate side between the first ground sheet and the second ground sheet, the signal conductor trace terminating in a device contact.

In some embodiments, the test probe assembly further comprises a ground sheet gap separating the first ground sheet from the second ground sheet, the ground sheet gap contiguous with a conductor slot formed between the first ground sheet and the second ground sheet and the conductor slot contiguous with the signal conductor trace. In some embodiments, the test probe assembly further comprises a test signal generator to provide a test signal to the test probe assembly and the test probe assembly electrically coupled to a device under test.

Consistent with the present disclosure, a test probe assembly comprises a mounting fixture, a lead frame mounted to the mounting fixture, and at least one radio frequency connector assembly electrically coupled with the lead frame, the at least one radio frequency connector assembly includes a connector body and a center conductor assembly, the center conductor assembly including a center conductor extending from a first end to a second end. In some embodiments, the lead frame comprises a substrate having a first substrate side, a first ground sheet secured on the first substrate side, a second ground sheet secured on the first substrate side, the second ground sheet physically separated from the first ground sheet, and a signal conductor trace secured on the first substrate side between the first ground sheet and the second ground sheet, the signal conductor trace terminating in a device contact.

In some embodiments, the test probe assembly further comprises a ground sheet gap separating the first ground sheet from the second ground sheet, the ground sheet gap contiguous with a conductor slot formed between the first ground sheet and the second ground sheet and the conductor slot contiguous with the signal conductor trace.

Consistent with the present disclosure, a method comprises, in the field, identifying a contactor including a first lead frame that requires replacement, removing the first lead frame from the contactor, and installing the second lead frame in the contactor. In some embodiments, removing the first lead frame from the contactor comprises removing the lead frame retainer mechanism and removing the first lead frame from the contactor. In some embodiments, installing the second lead frame in the contractor comprises inserting the second lead frame into the contactor and reinstalling the lead frame retainer mechanism.

Consistent with the present disclosure, an apparatus comprises a contactor including a first lead frame having a first pitch, the first lead frame being field replaceable without changing the contactor. In some embodiments, the first lead frame having the first pitch is field replaceable with a second contactor having a second pitch different from the first pitch.

Consistent with the present disclosure, a method comprises providing test signals through a probe including a lead frame having a first pitch to a device under test, and replacing the lead frame having a first pitch with a lead frame having a second pitch different from the first pitch to test the device under test or a second device under test.

### BRIEF DESCRIPTION OF THE FIGURES

FIG. 1 shows an illustration of a top view of a lead frame in accordance with some embodiments of the present disclosure;

FIG. 2 shows an illustration of a bottom view of the lead frame in accordance with some embodiments of the present disclosure;

FIG. 3 shows an illustration of a cross-sectional view of the lead frame including the substrate, the first ground sheet, and an adhesive along a line, as shown in FIG. 1, in accordance with some embodiments of the present disclosure;

FIG. 4 shows an illustration of a cross-sectional view of the lead frame including the substrate, the second ground sheet, and an adhesive along a line, as shown in FIG. 1, in accordance with some embodiments of the present disclosure;

FIGS. 5A, FIG. 5B, FIG. 5C, and FIG. 5D show illustrations of embodiments of signal and ground configurations for the lead frame in accordance with some embodiments of the present disclosure;

FIG. 5E shows an illustration of a perspective view of a test probe assembly including a mounting fixture, a lead frame including a co-planar waveguide (CPW), and one radio frequency connector assembly in accordance with some embodiments of the present disclosure;

FIG. 6 shows an illustration of a perspective view of a test probe assembly including a mounting fixture, a lead frame including a co-planar waveguide (CPW), and two radio frequency connector assemblies in accordance with some embodiments of the present disclosure;

FIG. 7 shows an illustration of the center conductor assembly, also shown in FIG. 6, in accordance with some embodiments of the present disclosure;

FIG. 8 shows an illustration of a signal conductor assembly in accordance with some embodiments of the present disclosure; and

FIG. 9 shows a block diagram of a test system including the test probe assembly including the lead frame coupling a test signal generator to a device under test (DUT) in accordance with some embodiments of the present disclosure.

### DETAILED DESCRIPTION

The following detailed description includes references to the accompanying drawings, which form a part of the detailed description. The drawings show, by way of illustration, specific embodiments in which the apparatus may be practiced. These embodiments, which are also referred to herein as “examples” or “options,” are described in enough detail to enable those skilled in the art to practice the present embodiments. The embodiments may be combined, other embodiments may be utilized or structural or logical changes may be made without departing from the scope of the invention. The following detailed description is, therefore, not to be taken in a limiting sense and the scope of the invention is defined by the appended claims and their legal equivalents.

In this document, the terms “a” or “an” are used to include one or more than one, and the term “or” is used to refer to a nonexclusive “or” unless otherwise indicated. The term “about” should be interpreted as plus or minus ten percent of the stated number or parameter unless otherwise indicated. In addition, it is to be understood that the phraseology or terminology employed herein, and not otherwise defined, is for the purpose of description only and not of limitation.

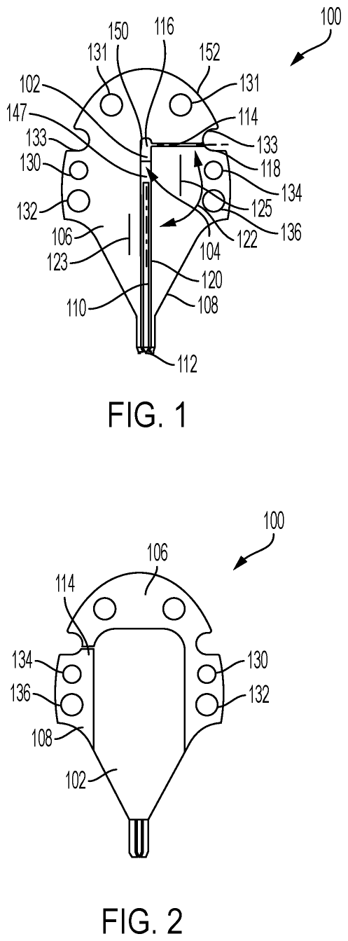

A test probe assembly 160, shown in FIG. 6, including a lead frame 100, shown in detail in FIG. 1, for testing integrated circuits is described herein, and shown in the drawings. The test probe assembly 160 includes a co-planar waveguide construction, combined with a mechanically mounted custom radio frequency (RF) connector to provide matched compliant probing mechanism for probing semiconductor devices, printed circuit boards (PCBs), substrates, a bare die, and other structures at frequencies up to 110 GHz or even up to 1 THz. The construction and assembly allows for simple customization and replacement of individual components. The probe assembly is more robust than previous probes, and can be repaired and configured in the field.

FIG. 1 shows an illustration of a top view of a lead frame 100 in accordance with some embodiments of the present disclosure. The lead 100 includes a substrate 102, a first ground sheet 106, a second ground sheet 108, and a signal conductor trace 110. In some embodiments, the substrate 102 is formed from a dielectric. The substrate 102 has a first substrate side 104. The first ground sheet 106 is secured on the first substrate side 104. The second ground sheet 108 is secured on the first substrate side 104. The second ground sheet 108 is physically separated from the first ground sheet 106. The signal conductor trace 110 is secured on the first substrate side 104 between the first ground sheet 106 and the second ground sheet 108. The signal conductor trace 110 terminates in a device contact 112.

In some embodiments, the first ground sheet 106 and the second ground sheet 108 are formed from a conductive material, such as a metal. In combination, the first ground sheet 106, the second ground sheet 108, and the signal conductor trace 110 form a co-planar waveguide transmission line that extends to a device contact 112. A co-planar waveguide includes strip conductor with two ground planes parallel and on either side of the strip conductor on the same substrate. In some embodiments, the lead frame 100 includes a ground sheet gap 114. The ground sheet gap 114 separates the first ground sheet 106 from the second ground sheet 108. The ground sheet gap 114 is contiguous with a conductor slot 116. The conductor slot 116 is formed in a space between the first ground sheet 106 and the second ground sheet 108 and physically separates the first ground sheet 106 from the second ground sheet 108. The conductor slot 116 exposes a section 150 of the first substrate side 104. The conductor slot 116 is located between the ground sheet gap 114 and the signal conductor trace 110.

The lead frame 100 includes an outside edge 152. The ground sheet gap 114 extends from the conductor slot 116 to the outside edge 152. The conductor slot 116 exposes a section 150 of the first substrate side 104. The conductor slot 116 is contiguous with the signal conductor trace 110.

The lead frame 100 includes mounting structures. In one or more embodiments, the mounting structures includes one or more screw holes 131. In one or more embodiments, the mounting structure includes one or more dowel pin slots 133. However, the lead frame 100 is not limited to a particular configuration of mounting structures. In some embodiments, the first ground sheet 106 has a first ground sheet mounting and alignment first hole 130 and a first ground sheet mounting and alignment second hole 132. In some embodiments, the second ground sheet 108 has a second ground sheet mounting and alignment first hole 134 and a second ground sheet mounting and alignment second hole 136. The mounting structures are used to receive the lead frame 100 and secure the lead frame 100 to a mounting fixture 162 (shown in FIG. 6 and described below). The mounting structures fixture enable the lead frame 100 to be interchanged for different device under test (DUT) requirements, and allows for the lead frame 100 to be replaceable.

FIG. 2 shows an illustration of a bottom view of the lead frame 100 in accordance with some embodiments of the present disclosure. The lead frame 100 includes the substrate 102, the first ground sheet 106, and the second ground sheet 108. The second ground sheet 108 is physically separated from the first ground sheet 106. In some embodiments, the lead frame 100 includes a ground sheet gap 114. The ground sheet gap 114 separates the first ground sheet 106 from the second ground sheet 108. The first ground sheet 106 has a first ground sheet mounting and alignment first hole 130 and a first ground sheet mounting and alignment second hole 132. The second ground sheet 108 has a second ground sheet mounting and alignment first hole 134 and a second ground sheet mounting and alignment second hole 136.

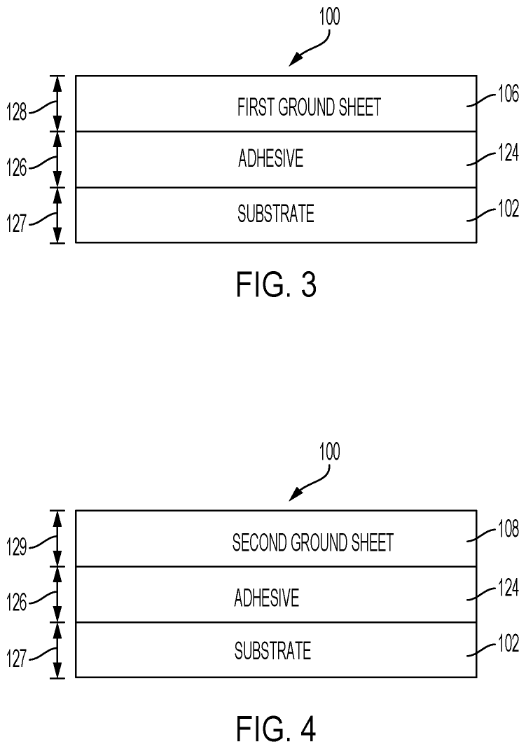

FIG. 3 shows an illustration of a cross-sectional view of the lead frame 100 including the substrate 102, the first ground sheet 106, and an adhesive 124 along a line 123, as shown in FIG. 1, in accordance with some embodiments of the present disclosure. Referring to FIG. 1 and FIG. 3, in some embodiments, the adhesive 124 (shown in FIG. 3) secures the first ground sheet 106 to the substrate 102. In a similar manner, as described below, the adhesive 124 secures the second ground sheet 108 to the substrate 102. Referring again to FIG. 3, the adhesive 124 has an adhesive thickness 126. In some embodiments, the adhesive thickness 126 is between zero and one-hundred microns. In some embodiments, the adhesive thickness 126 is between zero and twenty microns, zero and forty microns, zero and sixty microns, or zero and eighty microns. In some embodiments, the adhesive thickness 126 is between twenty and forty microns, forty and sixty microns, sixty and eighty microns, or eighty and one-hundred microns. The substrate 102 has a substrate thickness 127. In some embodiments, the substrate thickness 127 is between zero and two-hundred microns. In some embodiments, the substrate thickness 127 is between zero and fifty microns, zero and one-hundred microns, or zero and one-hundred fifty microns. In some embodiments, the substrate thickness 127 is between zero and fifty microns, fifty and one-hundred microns, one-hundred and one-hundred and fifty microns, or one-hundred fifty and two-hundred microns. In some embodiments, the substrate thickness is greater than two-hundred microns. The first ground sheet 106 has a first ground sheet thickness 128. In some embodiments, the first ground sheet thickness 128 is between thirteen and two-hundred and fifty microns. In some embodiment, the first ground sheet thickness 128 is between fifty and one-hundred and seventy-five microns. In some embodiments, the first ground sheet thickness 128 is about one-hundred and twenty-five microns.

FIG. 4 shows an illustration of a cross-sectional view of the lead frame 100 including the substrate 102, the second ground sheet 108, and an adhesive 124 along a line 125, as shown in FIG. 1, in accordance with some embodiments of the present disclosure. Referring to FIG. 1 and FIG. 4, in some embodiments, the adhesive 124 (shown in FIG. 4) secures the second ground sheet 108 to the substrate 102. Referring again to FIG. 4, the adhesive 124 has an adhesive thickness 126. In some embodiments, the adhesive thickness 126 is between zero and one-hundred microns. In some embodiments, the adhesive thickness 126 is between zero and twenty microns, zero and forty microns, zero and sixty microns, or zero and eighty microns. In some embodiments, the adhesive thickness 126 is between twenty and forty microns, forty and sixty microns, sixty and eighty microns, or eighty and one-hundred microns. The substrate 102 has a substrate thickness 127. In some embodiments, the substrate thickness 127 is between zero and two-hundred microns. In some embodiments, the substrate thickness 127 is between zero and fifty microns, zero and one-hundred microns, or zero and one-hundred fifty microns. In some embodiments, the substrate thickness 127 is between zero and fifty microns, fifty and one-hundred microns, one-hundred and one-hundred and fifty microns, or one-hundred fifty and two-hundred microns. In some embodiments, the substrate thickness is greater than two-hundred microns. The second ground sheet 108 has a second ground sheet thickness 129. In some embodiments, the second ground sheet thickness 129 is between thirteen and two-hundred and fifty microns. In some embodiments, the second ground sheet thickness 129 is between fifty and one-hundred and seventy-five microns. In some embodiments, the second ground sheet thickness 129 is about one-hundred and twenty-five microns.

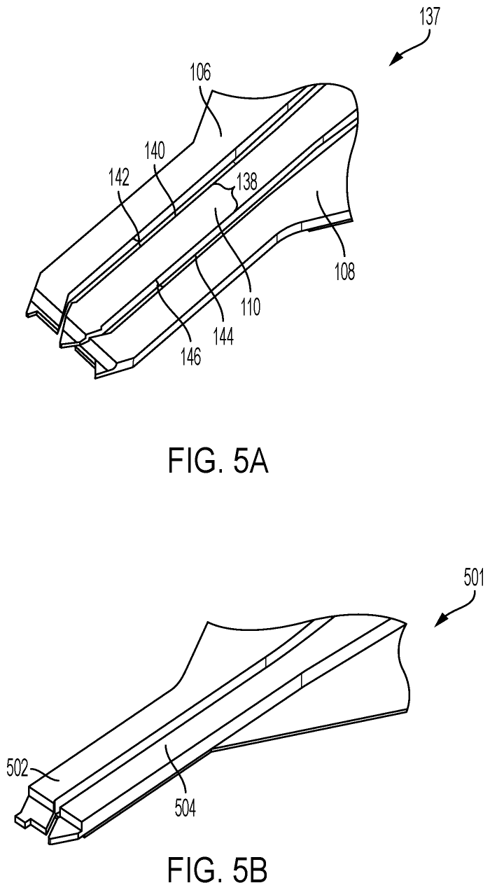

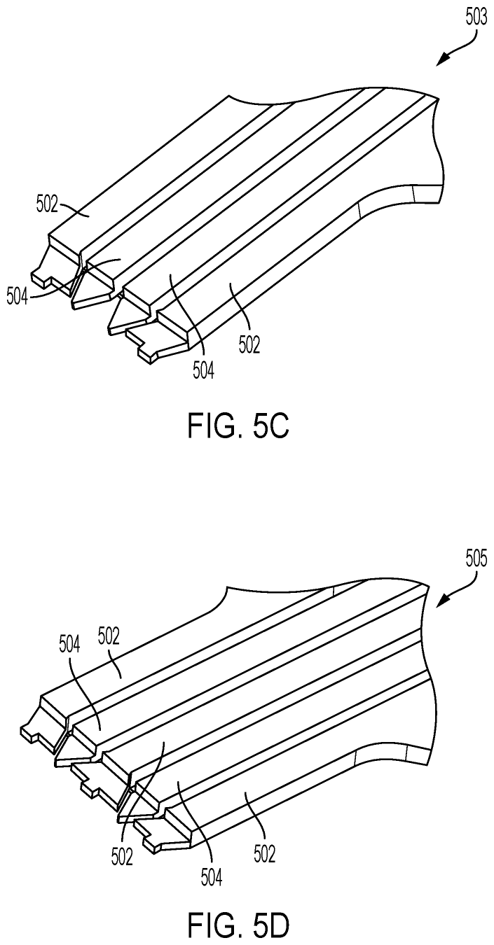

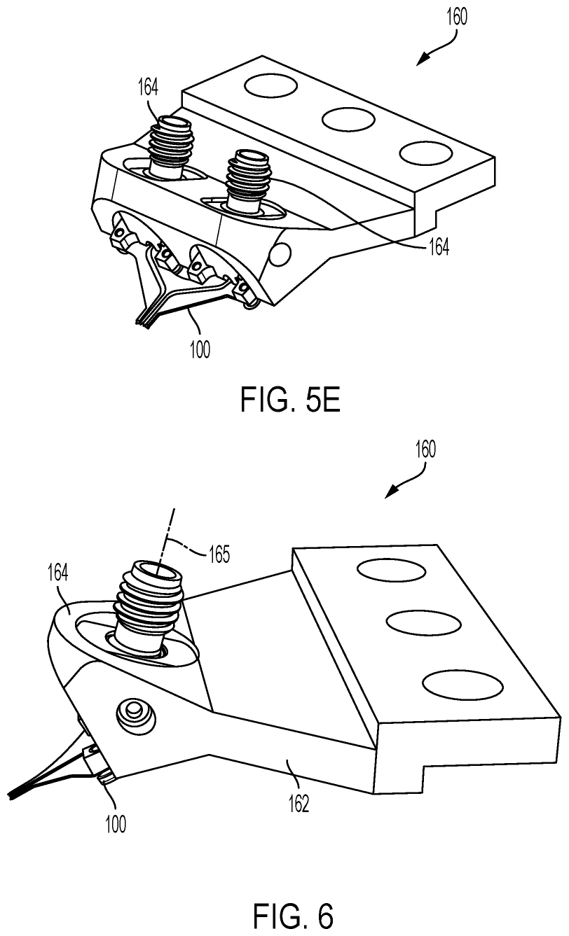

FIG. 5A, FIG. 5B, FIG. 5C, and FIG. 5D show illustrations of embodiments of signal and ground configurations for the lead frame 100 in accordance with some embodiments of the present disclosure. FIG. 5A shows an illustration of a portion 137 of the lead frame 100 (shown in FIG. 1) including the signal conductor trace 110, the first ground sheet 106, and the second ground sheet 108 which form a co-planar waveguide in accordance with some embodiments of the present disclosure. In one or more embodiments, the lead frame 100 includes a single ground-signal-ground co-planar waveguide, as shown in FIG. 5A. The signal conductor trace 110 has a signal conductor trace width 138. In some embodiments, the signal conductor trace width 138 is between fifty and six-hundred microns. In some embodiments, the signal conductor trace width 138 is between fifty and one-hundred fifty microns, one-hundred fifty and two-hundred fifty microns, two-hundred fifty and three-hundred fifty microns, three-hundred-fifty and four-hundred fifty, or four-hundred fifty and six-hundred microns. In some embodiments, the signal conductor trace width 138 is between about one-hundred and four-hundred microns. In some embodiments, the signal conductor trace width 138 is about three hundred microns. A first signal conductor trace gap 140 located between the signal conductor trace 110 and the first ground sheet 106 has a first signal conductor trace gap width 142. A second signal conductor trace gap 144 located between the signal conductor trace 110 and the second ground sheet 108 has a second signal conductor trace gap width 146. Referring again to FIG. 1, the conductor slot 116 has a conductor slot width 118 substantially equal to the signal conductor trace width 138 (shown in FIG. 5A) plus the first signal trace gap width 142 (shown in FIG. 5A) and the second signal conductor trace gap width 146 (shown in FIG. 5A). Referring to FIG. 1 and FIG. 5A, the conductor slot 116 (shown in FIG. 1) has a conductor slot width 147 substantially equal to the signal conductor trace width 138 plus the first signal conductor trace gap width 142 and the second signal conductor trace gap width 146.

The first conductor sheet 106, the second conductor sheet 108, the signal conductor trace width 139, the first signal conductor trace gap width 142, and the second signal conductor trace gap width 146, are configured to match to the impedance of the test equipment and to the impedance of the device under test (DUT). In one or more embodiments, the impedance is fifty ohms. The impedance can be tuned to fit the application.

In one or more embodiments, the lead frame 100 can support a single ended ground-signal (GS) transmission line 501, for instance, matched to fifty ohms, as shown in FIG. 5B. The single ended ground-signal (GS) transmission line 501 includes ground conductor 502 and signal conductor 504.

In one or more embodiments, the lead frame 100 includes a ground-signal-signal-ground (GSSG) co-planar waveguide transmission line 503, which are typically matched to a one-hundred ohm impedance, as shown in FIG. 5C. The ground-signal-signal-ground (GSSG) co-planar waveguide transmission line 503 includes ground conductors 502 and signal conductors 504. For a GSSG configuration, two connector assemblies would be mounted on a single assembly.

In one or more embodiments, the lead frame 100 is a single ground-signal-ground-signal-ground (GSGSG) co-planar waveguide transmission line 505, as shown in FIG. 5D. The single ground-signal-ground-signal-ground (GSGSG) co-planar waveguide transmission line 505 includes ground conductors 502 and signal conductors 504. For the GSGSG configuration, two RF connector assemblies 164 would be mounted on a single assembly 160, as shown in FIG. 5E.

For the lead frame 100 that includes multiple co-planar waveguide transmission lines, the lead frame 100 can be customized for any ground/signal pitch required for testing (typical pitches range from 50 um to 1250 um). Further, the lead frame 100 is replaceable and can be interchanged for different DUT requirements.

FIG. 6 shows an illustration of a perspective view of a test probe assembly 160 including a mounting fixture 162, a lead frame 100 including a co-planar waveguide (CPW), and at least one radio frequency connector assembly 164 in accordance with some embodiments of the present disclosure. The at least one radio frequency connector assembly 164 is electrically coupled with the lead frame 100. The lead frame 100 is mounted to the mounting fixture 162. The lead frame 100 is shown in FIGS. 1-5 and described above.

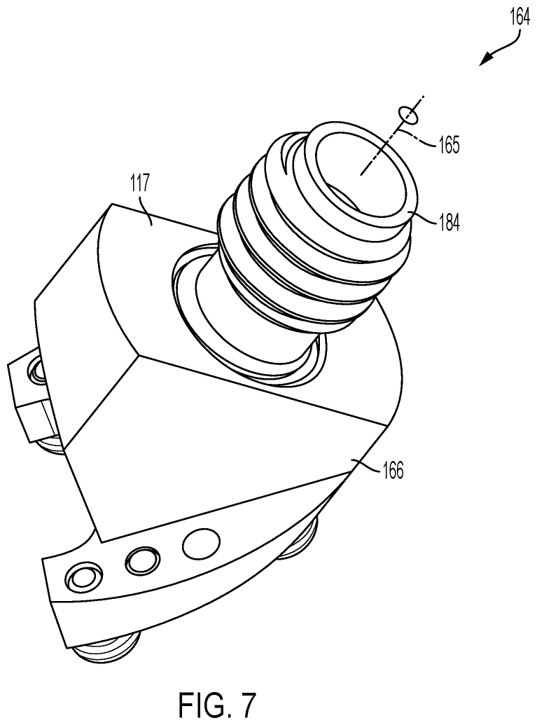

FIG. 7 shows an illustration of the center conductor assembly 164, also shown in FIG. 6, in accordance with some embodiments of the present disclosure. The at least one radio frequency connector assembly 164 is defined in part by a center line 165 or longitudinal axis, also shown in FIG. 6. The at least one radio frequency connector assembly 164 includes a connector body 166 and a connector 184. The connector body 166 includes a threaded opening 117 that receives the connector 184 therein. The connector 184 can be formed, for example, from common rod stock. The physical connection from the connector assembly 164 to the lead frame 100 is accomplished using cap screws located on the bottom of the connector assembly 164. The screw holes in the connector body 166 can be tapped to allow mounting of the lead frame 100 directly to the connector assembly 164 or they can be through holes to allow the connector to sandwich the lead frame 100 between the connector assembly 164 and another body of material under the lead frame 100. In one or more embodiments, the connector assembly 164 is angled relative to the lead frame 100, shown in FIG. 6, such that the center line 165 or longitudinal axis is disposed at a 45 degree angle relative to the plane of the lead frame 100. The 45 degree angle enables a matched impedance from the connector assembly 164 to the lead frame 100.

The at least one radio frequency connector assembly 164 enables connection from the lead frame 100 to the test equipment, such as a test signal generator, through, for example, 1 mm, 1.85 mm, 2.92 mm, and SMA standard connector interfaces. The connector assembly includes a threaded portion that can be replaceable for any cable standard available. The at least one radio frequency connector assembly 164 provides the shortest path from the cable to the lead frame 100 and is fully impedance configurable from the cable connection to the interface of the lead frame 100.

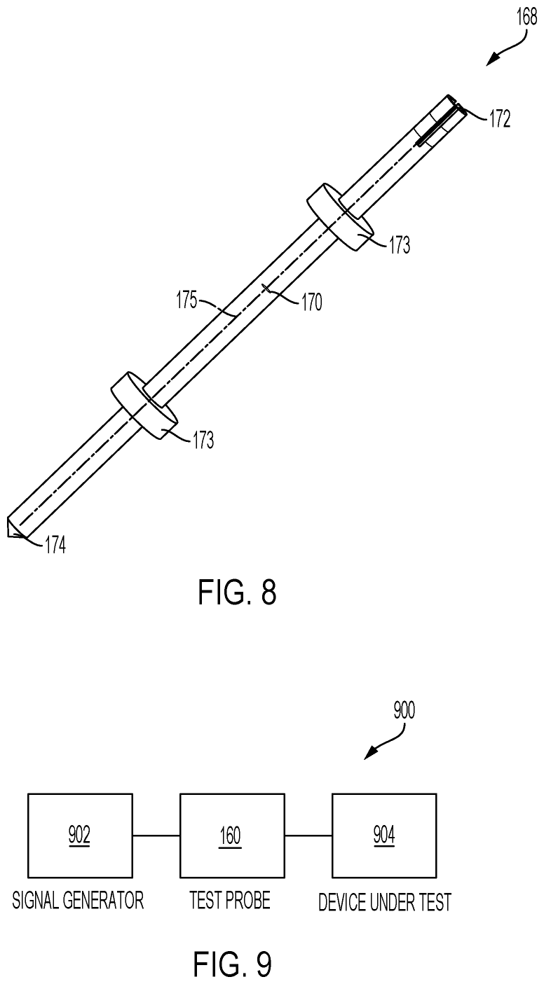

FIG. 8 shows an illustration of a signal conductor assembly 168 in accordance with some embodiments of the present disclosure. The signal conductor assembly 168 includes a center conductor 170 that extends from a first end 172 to a second end 174. In some embodiments, the signal conductor assembly 168 is enclosed in a cylindrical housing (not shown). The signal conductor assembly 168 is inserted into the connector 184 along the center line 165, shown in FIG. 6. The signal conductor assembly 168 including a center conductor body center line 175, when mounted as part of the test probe assembly 164, has the center conductor body center line 175 substantially aligned with the center conductor assembly center line 165 or longitudinal axis. In operation, the second end 174 is electrically coupled to the signal conductor trace 114, shown in FIG. 1. The first end 172 is coupled to a test signal generator.

The center conductor 170 of the signal conductor assembly 168 maximizes the impedance match at the interface between the center conductor 170 and the lead frame 100. The center conductor 170 is tapered and compression mounted, in one embodiment, to the lead frame 100 such that it ensures a reliable connection and provides optimal impedance match between the center connector 170 and the lead frame 100. The taper is angled to maximize the surface area of contact to the lead frame 100. In one or more embodiments, the signal conductor assembly 168 includes one or more spacers 173 that are mounted on the center conductor 170. In one or more embodiments, the one or more spacers 173 are cross-linked polystyrene microwave plastic spacers. In one or more embodiments, the one or more spacers 173 have a disc shape. The one or more spacers 173 are disposed between the center conductor 170 and a cylindrical house (not shown). In one or more embodiments, the center conductor 170 is formed of two or more, or three separate pieces that are press fit together. The one or more spacers 173 minimize the insertion loss of the conductor 170 while maintaining temperature capability to a desired temperature, for example 150 degrees C.

FIG. 9 shows a block diagram of a test system 900 including the test probe assembly 160 including the lead frame 100 coupling a test signal generator 902 to a device under test (DUT) 904. The test signal generator, in some embodiments, provides digital signals, analog signals, or mixed digital and analog signals to the test probe assembly 160. The test probe assembly 160 transmits the digital signals, analog signals or mixed digital and analog signals to the device under test 904. The device under test 904 is not limited to a particular type of electronic device or circuit. The device under test 904 may be any electronic circuit. In some embodiments, the device under test 904 is a microprocessor, a communication circuit, or a graphics processor.

It is to be understood that the above description is intended to be illustrative, and not restrictive. Many other embodiments will be apparent to those of skill in the art upon reading and understanding the above description. It should be noted that embodiments discussed in different portions of the description or referred to in different drawings can be combined to form additional embodiments of the present application. The scope should, therefore, be determined with reference to the appended claims, along with the full scope of equivalents to which such claims are entitled.

What is claimed is:

1. A lead frame comprising:
a substrate having a first substrate side;
a first ground sheet secured on the first substrate side;
a second ground sheet secured on the first substrate side, the second ground sheet physically separated from the first ground sheet; and
a signal conductor trace secured on the first substrate side between the first ground sheet and the second ground sheet, the signal conductor trace terminating in a device contact.

2. The lead frame of claim 1, further comprising a ground sheet gap separating the first ground sheet from the second ground sheet, the ground sheet gap contiguous with a conductor slot formed between the first ground sheet and the second ground sheet and the conductor slot contiguous with the signal conductor trace.

3. The lead frame of claim 2, wherein the ground sheet gap has a ground sheet gap center line, the signal conductor trace has a signal conductor trace center line, and the signal conductor trace center line and the ground sheet gap center line form an angle having an angle size greater than zero degrees and less than one-hundred eighty degrees.

4. The lead frame of claim 3, further comprising an adhesive to secure the first ground sheet to the substrate and to secure the second ground sheet to the substrate.

5. The lead frame of claim 4, wherein the adhesive has an adhesive thickness of between about zero and one-hundred microns.

6. The lead frame of claim 5, wherein the substrate has a substrate thickness of between about zero and two-hundred microns.

7. The lead frame of claim 6, wherein the first ground sheet has a first ground sheet thickness of between about thirteen and two-hundred and fifty microns.

8. The lead frame of claim 3, wherein the first ground sheet has a first ground sheet mounting and alignment first hole and a first ground sheet mounting and alignment second hole and the second ground sheet has a second ground sheet mounting and alignment first hole and a second ground sheet mounting and alignment second hole.

9. The lead frame of claim 8, wherein the signal conductor trace has a signal conductor trace width, a first signal conductor trace gap located between the signal conductor trace and the first ground sheet has a first signal conductor trace gap width and a second signal conductor trace gap located between the signal conductor trace and the second ground sheet has a second signal conductor trace gap width, and the conductor slot has a width substantially equal to the signal conductor trace width plus the first signal conductor trace gap width and the second signal conductor trace gap width.

10. The lead frame of claim 3, wherein the first ground sheet and the second ground sheet form a conductor slot that exposes a section of the first substrate side, the conductor slot located between the ground sheet gap and the signal conductor trace.

11. The lead frame of claim 10, wherein the signal conductor trace has a signal conductor trace width, a first signal trace gap has a first signal trace gap width and a second signal trace gap has a second signal trace gap width, and the conductor slot has a conductor slot width substantially equal to the signal conductor trace width plus the first signal trace gap width and the second signal trace gap width.

12. The apparatus of claim 11, wherein the signal conductor trace width is between about fifty and about six-hundred microns.

13. The lead frame of claim 12, wherein the lead frame includes an outside edge and the ground sheet gap extends from the conductor slot to the outside edge.

14. The lead frame of claim 3, wherein the conductor slot exposes a section of the first substrate side.

15. A test probe assembly comprising:
a mounting fixture;
a lead frame mounted to the mounting fixture; and
at least one radio frequency connector assembly electrically coupled with the lead frame.

16. The test probe assembly of claim 15, wherein the lead frame comprises:
a substrate having a first substrate side;
a first ground sheet secured on the first substrate side;
a second ground sheet secured on the first substrate side, the second ground sheet physically separated from the first ground sheet; and
a signal conductor trace secured on the first substrate side between the first ground sheet and the second ground sheet, the signal conductor trace terminating in a device contact.

17. The test probe assembly of claim 16, further comprising a ground sheet gap separating the first ground sheet from the second ground sheet, the ground sheet gap contiguous with a conductor slot formed between the first ground sheet and the second ground sheet and the conductor slot contiguous with the signal conductor trace.

18. The test probe assembly of claim 16, further comprising a test signal generator to provide a test signal to the test probe assembly and the test probe assembly electrically coupled to a device under test.

19. A test probe assembly comprising:
a mounting fixture;
a lead frame mounted to the mounting fixture; and
at least one radio frequency connector assembly electrically coupled with the lead frame, the at least one radio frequency connector assembly includes a connector body and a center conductor assembly, the center conductor assembly including a center conductor extending from a first end to a second end.

20. The test probe assembly of claim 19, wherein the lead frame comprises:
a substrate having a first substrate side;
a first ground sheet secured on the first substrate side;
a second ground sheet secured on the first substrate side, the second ground sheet physically separated from the first ground sheet; and
a signal conductor trace secured on the first substrate side between the first ground sheet and the second ground sheet, the signal conductor trace terminating in a device contact.

21. The test probe assembly of claim 20, further comprising a ground sheet gap separating the first ground sheet from the second ground sheet, the ground sheet gap contiguous with a conductor slot formed between the first ground sheet and the second ground sheet and the conductor slot contiguous with the signal conductor trace.

22. A method comprising:
identifying a contactor including a first lead frame that requires replacement;
removing the first lead frame from the contactor; and
installing the second lead frame in the contactor.

23. The method of claim 22, wherein removing the first lead frame from the contactor comprises removing the lead frame retainer mechanism and removing the first lead frame from the contactor.

24. The method of claim 23, wherein installing the second lead frame in the contractor comprises inserting the second lead frame into the contactor and reinstalling the lead frame retainer mechanism.

25. An apparatus comprising:
a contactor including a first lead frame having a first pitch, the first lead frame being field replaceable without changing the contactor.

26. The apparatus of claim 25, wherein the first lead frame having the first pitch is field replaceable with a second lead frame having a second pitch different from the first pitch.

27. A method comprising:
providing test signals through a probe including a lead frame having a first pitch to a device under test; and
replacing the lead frame having a first pitch with a lead frame having a second pitch different from the first pitch to test the device under test or a second device under test.
